(19) United States
(12) Patent Application Publication
(10) Pub. No.: US 2024/0268150 A1
(43) Pub. Date: Aug. 8, 2024

(54) LIGHT EMITTING DEVICE, DISPLAY DEVICE, PHOTOELECTRIC CONVERSION DEVICE, ELECTRONIC APPARATUS, ILLUMINATION DEVICE, MOVING BODY, AND WEARABLE DEVICE

(71) Applicant: CANON KABUSHIKI KAISHA, Tokyo (JP)

(72) Inventor: MASASHI KUSUKAWA, Kanagawa (JP)

(21) Appl. No.: 18/421,012

(22) Filed: Jan. 24, 2024

(30) Foreign Application Priority Data
Feb. 7, 2023 (JP) 2023-017008

(51) Int. Cl. H10K 59/121; H10K 59/123; H10K 59/131

(52) U.S. Cl. CPC H10K 59/1213; H10K 59/1216; H10K 59/123; H10K 59/131

(57) ABSTRACT

A light emitting device is provided. The device has a structure in which a first substrate and a second substrate are stacked on each other, and includes a pixel including a light emitting element, a first transistor and a second transistor. A source region and a drain region of the first transistor are arranged in a first well region provided on a first surface of the first substrate, a source region and a drain region of the second transistor are arranged in a second well region provided on a second surface of the second substrate, and a conductivity type of the first well region and a conductivity type of the second well region are different from each other.

### BACKGROUND OF THE INVENTION

### Field of the Invention

The present invention relates to a light emitting device, a display device, a photoelectric conversion device, an electronic apparatus, an illumination device, a moving body, and a wearable device.

### Description of the Related Art

Japanese Patent Laid-Open No. 2008-281671 describes a pixel circuit that includes a p-channel transistor (to be sometimes referred to as a p-type transistor) and an n-channel transistor (to be sometimes referred to as an n-type transistor).

### SUMMARY OF THE INVENTION

In the arrangement described in Japanese Patent Laid-Open No. 2008-281671, it is necessary to form, in a substrate, well regions of different conductivity types and arrange the p-type transistor and the n-type transistor in the respective regions. In a miniaturized pixel, the transistor of the first conductivity type (one of the p type and the n type) is close to the well region of the first conductivity type where the transistor of the second conductivity type (the other one of the p type and the n type) is arranged. When the transistor of the first conductivity type is close to the well region of the first conductivity type, the depletion layer extending from the drain region of the transistor of the first conductivity type may be connected to the well region of the first conductivity type, and an off leakage current may increase. An increase of the off leakage current can cause a degradation of image quality such as a degradation of contrast.

Some embodiments of the present invention provide a technique advantageous in decreasing an off leakage current.

According to some embodiments, a light emitting device that has a structure in which a first substrate and a second substrate are stacked on each other, and comprises a pixel including a light emitting element, a first transistor, and a second transistor, wherein a source region and a drain region of the first transistor are arranged in a first well region provided on a first surface of the first substrate, a source region and a drain region of the second transistor are arranged in a second well region provided on a second surface of the second substrate, and a conductivity type of the first well region and a conductivity type of the second well region are different from each other, is provided.

Further features of the present invention will become apparent from the following description of exemplary embodiments (with reference to the attached drawings).

### BRIEF DESCRIPTION OF THE DRAWINGS

FIG. 1 is a view showing an example of the arrangement of a light emitting device according to an embodiment;

FIG. 2 is a circuit diagram showing an example of the arrangement of a pixel arranged in the light emitting device shown in FIG. 1;

FIG. 3 is a sectional view showing an example of the arrangement of the light emitting device shown in FIG. 1;

FIG. 4 is a sectional view showing an example of the arrangement of the light emitting device shown in FIG. 1;

FIG. 5 is a sectional view showing an example of the arrangement of the light emitting device shown in FIG. 1;

FIG. 6 is a sectional view showing an example of the arrangement of the light emitting device shown in FIG. 1;

FIG. 7 is a sectional view showing an example of the arrangement of the light emitting device shown in FIG. 1;

FIGS. 8A and 8B are sectional views showing an example of the arrangement of the pixel of the light emitting device shown in FIG. 1;

FIGS. 9A to 9C are views showing an example of an image forming device using the light emitting device according to the embodiment;

FIG. 10 is a view showing an example of a display device using the light emitting device according to the embodiment;

FIG. 11 is a view showing an example of a photoelectric conversion device using the light emitting device according to the embodiment;

FIG. 12 is a view showing an example of an electronic apparatus using the light emitting device according to the embodiment;

FIGS. 13A and 13B are views each showing an example of a display device using the light emitting device according to the embodiment;

FIG. 14 is a view showing an example of an illumination device using the light emitting device according to the embodiment;

FIG. 15 is a view showing an example of a moving body using the light emitting device according to the embodiment; and

FIGS. 16A and 16B are views each showing an example of a wearable device using the light emitting device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

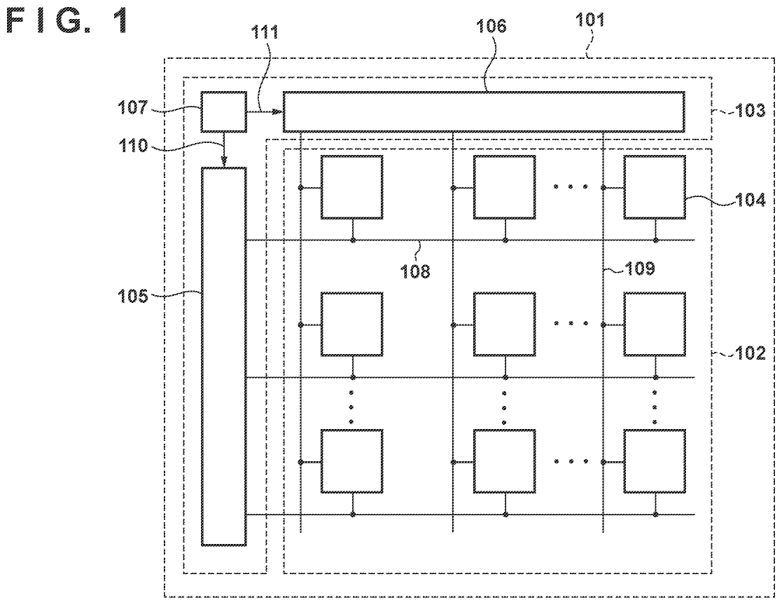

With reference to FIGS. 1 to 7, a light emitting device according to an embodiment of the present disclosure will be described. FIG. 1 is a system diagram showing an outline of a light emitting device 101 according to this embodiment. As shown in FIG. 1, the light emitting device 101 includes a pixel array 102, and a peripheral circuit portion 103 arranged in the periphery of the pixel array 102.

In the pixel array 102, a plurality of pixels 104 are two-dimensionally arranged in, for example, a matrix. Each pixel 104 includes a light emitting element such as an organic electroluminescence (EL) element, a semiconductor laser element, a light emitting diode, or the like. In the peripheral circuit portion 103, driving circuits for driving the pixels 104 (pixel array 102) are arranged. The driving circuits arranged in the peripheral circuit portion 103 can include, for example, a vertical scanning circuit 105, a signal output circuit 106, and a control circuit 107. In the pixel array 102, a scanning line 108 is arranged for each pixel row along the row direction (the horizontal direction in FIG. 1). Further, in the pixel array 102, a signal line 109 is arranged for each pixel column along the column direction (the vertical direction in FIG. 1). The control circuit 107 can supply a vertical scanning control signal 110 to the vertical scanning circuit 105, and supply a signal output signal 111 to the signal output circuit 106. The scanning line 108 is connected to the output terminal of the vertical scanning circuit 105 in the corresponding row. The signal line 109 is connected to the output terminal of the signal output circuit 106 in the corresponding column. The vertical scanning circuit 105 supplies a write signal to each scanning line 108 in accordance with the vertical scanning control signal 110 supplied from the control circuit 107. The signal output circuit 106 captures the image data supplied from the control circuit 107 in accordance with the signal output signal 111. The signal output circuit 106 D/A-converts the image data, thereby supplying the luminance signal corresponding to the value of the image data to each signal line 109.

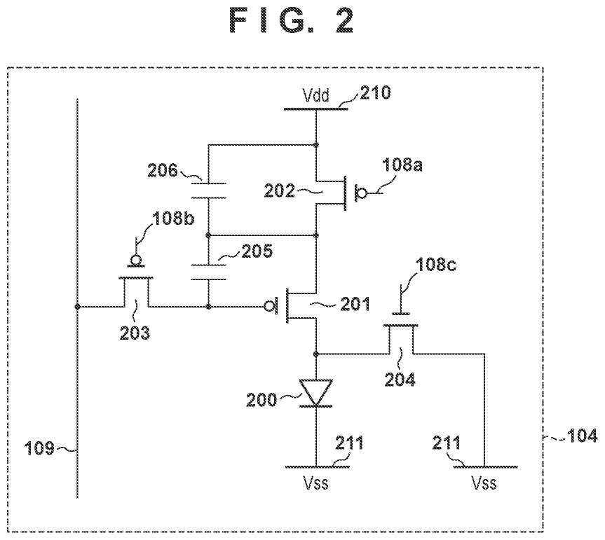

FIG. 2 is a circuit diagram showing an example of the arrangement of the pixel 104 arranged in the light emitting device 101. As shown in FIG. 2, the pixel 104 includes a light emitting element 200. The light emitting element 200 includes an organic layer including a light emitting layer between the anode and the cathode. In this embodiment, the light emitting element 200 is an organic EL element. The organic layer may include, in addition to the light emitting layer, at least one or more of a hole injection layer, a hole transport layer, an electron injection layer, an electron transport layer, and an electron generation layer, as appropriate.

The pixel circuit arranged in each pixel 104 can include four transistors of a driving transistor 201, a light emission control transistor 202, a write transistor 203, and a reset transistor 204, and two electrostatic capacitances 205 and 206. The pixel 104 is supplied with a power supply potential Vdd from a supply line 210 and a power supply potential Vss from a supply line 211. Each of the four transistors of the driving transistor 201, the light emission control transistor 202, the write transistor 203, and the reset transistor 204 can be a MISFET (MOSFET). The vertical scanning circuit 105 supplies a write signal to the gate of the light emission control transistor 202, the gate of the write transistor 203, and the gate of the reset transistor 204 via scanning lines 108a to 108c, respectively. The signal line 109 is connected to the source of the write transistor 203. When the write transistor 203 is set in the ON (conductive) state, the potential (for example, the luminance signal) of the signal line 109 is input to the gate of the driving transistor 201. The value of current flowing between the source and drain of the driving transistor 201 is decided in accordance with the potential of the luminance signal, and the light emission luminance of the light emitting element 200 is controlled. The drain of the driving transistor 201 is connected to the anode of the light emitting element 200 and the source of the reset transistor 204. When the reset transistor 204 is set in the ON state, the potential difference between the terminals of the light emitting element 200 is reset, so no current flows through the light emitting element 200 and the light emitting element 200 does not emit light. Both the cathode of the light emitting element 200 and the drain of the reset transistor 204 may be connected to the supply line 211 so that they may have the same potential (power supply potential Vss). The setting of the potential of each of the power supply potential Vdd and the power supply potential Vss is decided to an appropriate value, as appropriate, in accordance with the characteristics of the light emitting element 200.

In this embodiment, as shown in FIG. 2, each of the driving transistor 201, the light emission control transistor 202, and the write transistor 203 is a p-channel MIS transistor (to be sometimes referred to as a p-type transistor hereinafter). The reset transistor 204 is an n-channel MIS transistor (to be sometimes referred to as an n-type transistor hereinafter). However, the combination of the p-type transistor and the n-type transistor is not limited to this. As long as the light emitting element 200 can be caused to emit light with the luminance corresponding to the luminance signal supplied to the signal line 109, the combination of the p-type transistor and the n-type transistor may be any combination. Further, the number of transistors included one pixel 104 is not limited to four. For example, the light emission control transistor 202 may not be arranged. Alternatively, an additional transistor may be arranged in the pixel 104. The electrostatic capacitances 205 and 206 may be the parasitic capacitances of the transistors 201 and 202, respectively, or a capacitive element such as a MIS capacitor or a MIM capacitor may be arranged. However, in this embodiment, a description will be given assuming that one pixel 104 includes p-type and n-type transistors.

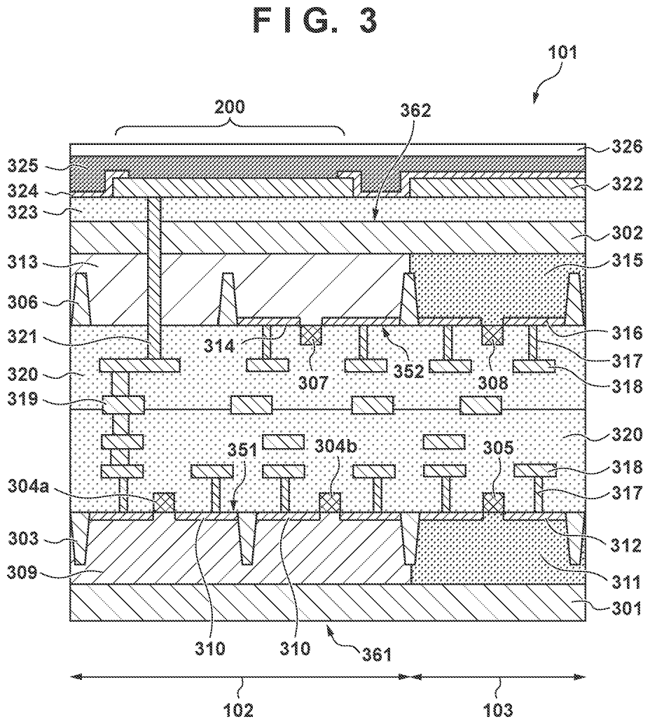

FIG. 3 is a sectional view showing an example of the arrangement of the light emitting device 101. The light emitting device 101 has a structure in which a substrate 301 and a substrate 302 are stacked on each other. Each of the substrate 301 and the substrate 302 may be a single-crystal silicon substrate or a Silicon on Insulator (SOI) substrate. A description will be given assuming that the conductivity type of each of the substrates 301 and 302 is the p type in the arrangement shown in FIG. 3.

Transistors 304 and 305, which are electrically isolated from each other by an element isolation region 303 formed by a Shallow Trench Isolation (STI) method, a selective oxidation method (LOCOS), or the like, are arranged in the substrate 301. The transistor 304 represents a transistor included in the pixel circuit which is arranged in the pixel array 102 and configured to drive each pixel 104. The transistor 305 represents a transistor forming the driving circuit or the like arranged in the peripheral circuit portion 103. Transistors 307 and 308, which are electrically isolated from each other by an element isolation region 306 formed by the STI method, the LOCOS method, or the like, are arranged in the substrate 302. The transistor 307 represents a transistor included in the pixel circuit which is arranged in the pixel array 102 and configured to drive each pixel 104. The transistor 308 represents a transistor forming the driving circuit or the like arranged in the peripheral circuit portion 103.

The transistor 304 forming the pixel circuit arranged in the substrate 301 is a p-type transistor. A diffusion layer (to be sometimes referred to as a source/drain region 310 hereinafter) forming the source region or the drain region of the transistor 304 is arranged in a well region 309 which is an n-type diffusion layer provided on a surface 351 of the p-type substrate 301. The source/drain region 310 is a p-type diffusion layer. The transistor 305 forming the driving circuit or the like arranged in the peripheral circuit portion 103 of the substrate 301 may be an n-type transistor or a p-type transistor. For example, the transistor 305 is an n-type transistor, and a diffusion layer (to be sometimes referred to as a source/drain region 312 hereinafter) forming the source region and the drain region is arranged in a well region 311 which is a p-type diffusion layer provided on the surface 351 of the p-type substrate 301. The source/drain region 312 is an n-type diffusion layer.

The transistor 307 forming the pixel circuit arranged in the substrate 302 is an n-type transistor. A diffusion layer (to be sometimes referred to as a source/drain region 314 hereinafter) forming the source region or the drain region of the transistor 307 is arranged in a well region 313 which is a p-type diffusion layer provided on a surface 352 of the p-type substrate 302. The source/drain region 314 is an n-type diffusion layer. The transistor 308 forming the driving circuit or the like arranged in the peripheral circuit portion 103 of the substrate 302 may be an n-type transistor or a p-type transistor. For example, the transistor 308 is an n-type transistor, and a diffusion layer (to be sometimes referred to as a source/drain region 316 hereinafter) forming the source region or the drain region is arranged in a well region 315 which is a p-type diffusion layer provided on the surface 352 of the p-type substrate 302. The source/drain region 316 is an n-type diffusion layer.

In the arrangement shown in FIGS. 2 and 3, the transistors 304 correspond to the driving transistor 201, the light emission control transistor 202, and the write transistor 203. For example, a leftmost transistor 304a among the transistors 304 shown in FIG. 3 is the driving transistor 201 whose drain is connected to the light emitting element 200. Further, in the arrangement shown in FIGS. 2 and 3, the transistor 307 corresponds to the reset transistor 204. In this manner, the transistors 304 as the p-type transistors and the transistor 307 as the n-type transistor arranged in one pixel 104 are arranged in the well regions 309 and 313 of different conductivity types in the different substrates 301 and 302, respectively. With this, even if miniaturization of the pixel 104 advances, in the substrate 301, the p-type well region is less likely to be arranged close to the source/drain region 310 of the transistor 304. Similarly, in the substrate 302, the n-type well region is less likely to be arranged close to the source/drain region 314 of the transistor 307. Therefore, an off leakage current in each of the transistors 304 and 307 decreases, so that a degradation of image quality in the light emitting device 101 such as a degradation of contrast can be suppressed. Details will be described later.

As the transistors 305 and 308 arranged in the peripheral circuit portion 103, both the n-type transistor and the p-type transistor may be provided in the same substrate 301 or 302, or only the transistors of one conductivity type may be provided. The transistors 305 and 308 may be provided only in one of the substrates 301 and 302 and may not be provided in the other substrate. In other words, in the light emitting device 101, only one of the transistor 305 and the transistor 308 may be provided. It can also be said that at least a part of the driving circuit for driving the pixel 104 (pixel array 102) is arranged on at least one of the surface 351 of the substrate 301 and the surface 352 of the substrate 302.

The transistors 304, 305, 307, and 308 can be formed by a general CMOS process. The dimensions such as the gate lengths of the transistors 304, 305, 307, and 308, and the impurity concentrations and depths of the source/drain regions 310, 312, 314, and 316 may be the same between the substrate 301 and the substrate 302, or may be different therebetween to optimize the respective components. This also applies to formation of silicide in each of the gate of the transistors 304, 305, 307, and 308 and the source/drain regions 310, 312, 314, and 316. For example, the dimension of the transistor 304 and the dimension of the transistor 307 can be different from each other since their conductivity types are different. Further, the dimensions of the transistors 304 and 307 forming the pixel circuit of each pixel 104 arranged in the pixel array 102 can be different from the dimensions of the transistors 305 and 308 forming the driving circuit or the like arranged in the peripheral circuit portion 103. For example, no silicide may be formed in the transistors 304 and 307, but silicide may be formed in the transistors 305 and 308. On the other hand, if the transistor 305 and the transistor 308 are of the same conductivity type, they may have the same dimension. In order to improve the hot carrier resistance, the transistors 304, 305, 307, and 308 may have a transistor structure of an offset structure in which the source/drain regions 310, 312, 314, and 316 are separated from the corresponding gate electrodes, respectively.

Between the surface 351 of the substrate 301 and the surface 352 of the substrate 302, contact plugs 317, wiring layers 318, wiring bonding portions 319, and insulating layers 320 are arranged as a wiring structure. Each of the transistors 304 and 307 is connected to the wiring layer 318 via the contact plug 317. Further, the wiring bonding portion 319 (including, for example, a Cu—Cu bonding) connects the wiring layers 318, thereby electrically connecting the substrate 301 and the substrate 302. For the contact plug 317 and the wiring layer 318, for example, copper (Cu), tungsten (W), aluminum (Al), or an alloy thereof may be used. For the wiring bonding portion 319, for example, copper or an alloy thereof may be used. For the insulating layer 320, silicon oxide (SiO₂), silicon nitride (SiN), silicon carbide (SiC), or the like may be used.

The light emitting element 200 includes an organic layer 325 including a light emitting layer, and an electrode 322 arranged between the light emitting layer (organic layer 325) and the substrate 301. Further, the light emitting element 200 includes an electrode 326 on the organic layer 325. The light emitting element 200 further includes an insulating layer 324 that covers the periphery portion of the electrode 322 to insulate the electrode 322 for each pixel 104. For example, silicon oxide or the like is used for the insulating layer 324. The organic layer 325 includes, as the light emitting layer, a self-light emitting material such as an organic electroluminescence material. In the pixel array 102, for example, an opening is provided in the insulating layer 324 on the electrode 322 serving as the anode. The opening provided in the insulating layer 324 electrically connects the electrode 322 and the organic layer 325, so that a current can flow through the organic layer 325 including the light emitting layer between the electrode 322 and the electrode 326. On the other hand, in the peripheral circuit portion 103, the insulating layer 324 includes no opening on the electrode 322, so the electrode 322 and the organic layer 325 are not electrically connected. Alternatively, for example, the electrode 322 may not be formed in the peripheral circuit portion 103.

For the electrode 322, for example, a metal such as tungsten, aluminum, or silver (Ag) may be used. As shown in FIG. 3, in an orthogonal projection with respect to the surface 351 of the substrate 301, at least a part of the transistor 304 and at least a part of the transistor 307 are arranged so as to overlap the electrode 322. With this arrangement, the electrode 322 can be used as a light shielding layer.

In the arrangement shown in FIG. 3, the substrate 302 is arranged between the light emitting element 200 and the substrate 301. In addition, the surface 351 of the substrate 301 where the well region 309 is provided and the surface 352 of the substrate 302 where the well region 313 is provided are arranged so as to face each other. In this case, the transistor 304a is connected to the electrode 322 via a conductive plug 321 extending through the substrate 302.

The conductive plug 321 is formed by embedding, via an insulating layer made of silicon oxide or the like, a metal such as copper, tungsten, or aluminum in a through hole provided in the substrate 302. The transistor 304a is electrically connected, via the conductive plug 321, to the electrode 322 of the light emitting element 200 formed on the substrate 302.

An insulating layer 323 is arranged between the electrode 322 of the light emitting element 200 and the substrate 302. The insulating layer 323 may be formed of, for example, silicon oxide or the like. A leakage current of each of the transistors 307 and 308 may increase due to damage on the substrate 302 upon thinning the substrate 302 by using a CMP method or the like. In order to decrease the leakage current of each of the transistors 307 and 308, an insulating layer made of aluminum oxide (Al₂O₃) having a negative fixed electric charge or an insulating layer made of silicon nitride having a positive fixed electric charge may be formed in the pixel array 102 or the peripheral circuit portion 103 so as to be in contact with a surface 362 of the substrate 302. In the arrangement shown in FIG. 3, there is a remaining region of the substrate 302 where the well regions 313 and 315 are not formed. However, in order to reduce the depth of the conductive plug 321, the thickness of the substrate 302 may be reduced up to the region where the well regions 313 and 315 are formed.

As has been described above, the transistor 304 arranged in the substrate 301 and forming the pixel circuit of each pixel 104 and the transistor 307 arranged in the substrate 302 are transistors of different conductivity types. The well regions 309 and 313 where the transistors 304 and 307 forming the pixel circuit are arranged, respectively, are formed to have either a p-type conductivity or an n-type conductivity in the substrates 301 and 302, respectively. In this embodiment, an example has been described in which the well region 309 as the n-type diffusion layer is arranged in the substrate 301, and the well region 313 as the p-type diffusion layer is arranged in the substrate 302. However, for example, the conductivity types of the substrates 301 and 302 and the well regions 309 and 313 may be reversed.

Further, for example, as each of the electrostatic capacitances 205 and 206, a MIS capacitor of the same polarity as the transistor 304 may be arranged in the well region 309 of the substrate 301. Alternatively, for example, as each of the electrostatic capacitances 205 and 206, a MIS capacitor of the same polarity as the transistor 307 may be arranged in the well region 313 of the substrate 302. In this case, in order to increase the capacitance of the MIS capacitor, the impurity concentration of the MIS capacitor in the surface of each of the well regions 309 and 313 may be different from that of each of the transistors 304 and 307.

When forming a transistor in a silicon substrate, in general, an n-type transistor is formed in a p-type well region formed by an impurity diffusion layer made of boron or the like, and a p-type transistor is formed in an n-type well region formed by an impurity diffusion layer made of phosphorus, arsenic, or the like. Consider a case of forming an n-type transistor and a p-type transistor in a limited region such as a pixel of a light emitting device and in the same substrate. In this case, for example, in an operation of the n-type transistor, there is a concern that a depletion layer extending from the drain (n-type impurity layer) connects to the n-type well region where the adjacent p-type transistor is arranged, and thus an off leakage current increases. Therefore, the drain of the transistor and the well region where the adjacent transistor of the different conductivity type need to be provided while being spaced apart from each other by a distance which prevents the depletion layer extending from the drain of the transistor from connecting to the well region. Hence, in the light emitting device, miniaturization of the pixel arranged in the pixel array becomes difficult.

On the other hand, in this embodiment, the transistor 304 and the transistor 307 are arranged in the substrate 301 and the substrate 302, respectively, to avoid formation of the transistors 304 and 307 of different conductivity types in the same substrate. Accordingly, in the pixel array 102, the conductivity type of each of the well regions 309 and 313 in the substrates 301 and 302, respectively, is decided to be one conductivity type. Hence, even if the pixel 104 is miniaturized in the light emitting device 101, an off leakage current of each of the transistors 304 and 307 can be suppressed. As a result, a degradation of image quality in the light emitting device 101 such as a degradation of contrast can be suppressed. As a result, the resolution and image quality can be improved in the light emitting device 101.

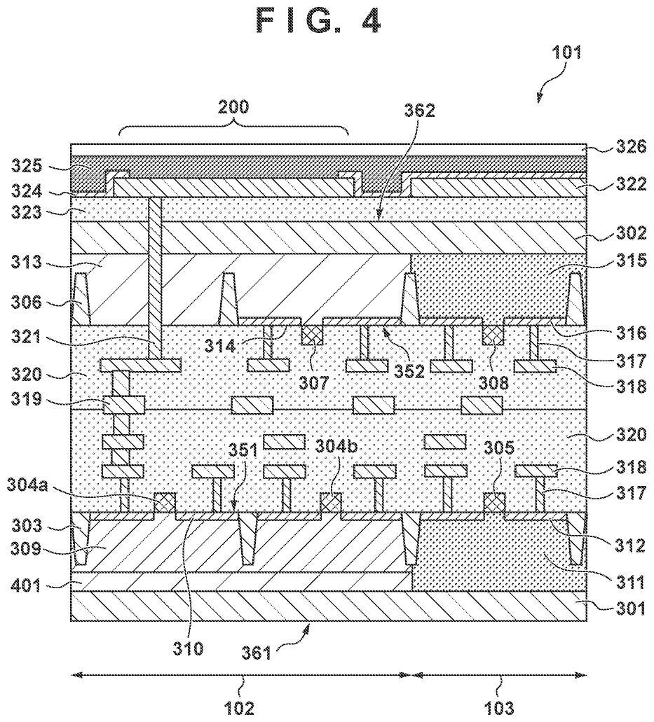

FIG. 4 is a sectional view showing an example of the arrangement of the light emitting device 101, and shows a modification of the sectional view shown in FIG. 3. In the arrangement shown in FIG. 4, a well region 401 in contact with the well region 309 and having a conductivity type different from that of the well region 309 is arranged between the well region 309 and a surface 361 on the opposite side of the surface 351 of the substrate 301 where the well region 309 is provided. In other words, the well region 401 as a diffusion layer of the conductivity type different from that of the well region 309 is provided at a position deeper than the well region 309 where the transistor 304 is arranged in the substrate 301. The remaining arrangement may be similar to that shown in FIG. 3 described above, so that different points will be mainly described.

Similar to the arrangement shown in FIG. 3, when the transistor 304 is a p-type transistor, the well region 309 is an n-type diffusion layer, and the well region 401 is a p-type diffusion layer. In this case, the conductivity type of the substrate 301 may be the n-type, or the well region 401 may be formed in an n-type well region provided in the substrate 301.

In the arrangement shown in FIG. 4, the well region 401 is arranged only with respect to the transistor 304, but the present invention is not limited to this. For example, in the substrate 302, a well region as an n-type diffusion layer may be arranged between the p-type substrate 302 and the p-type well region 313 where the transistor 307 is arranged.

If the well region 401 is arranged, when a back bias voltage is desirably applied to the well region 309 to control the threshold of the transistor 304, a back bias voltage different from that of the substrate 301 can be applied to the well region 309. By using the arrangement shown in FIG. 4, as compared to the arrangement shown in FIG. 3, it is possible to suppress an off leakage current of each of the transistors 304 and 307 arranged in the pixel 104 of the light emitting device 101 while improving the degree of freedom of threshold control of the transistor 304.

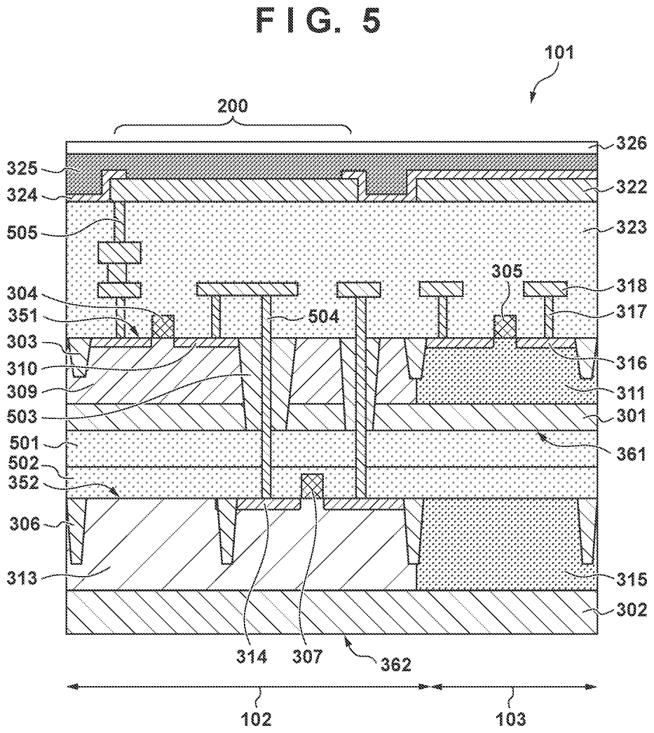

FIG. 5 is a sectional view showing an example of the arrangement of the light emitting device 101, and shows a modification of the sectional views shown in FIGS. 3 and 4. In the arrangements shown in FIGS. 3 and 4, the substrate 302 is arranged between the light emitting element 200 and the substrate 301. In addition, the surface 351 of the substrate 301 on which the well region 309 is provided and the transistor 304 is arranged and the surface 352 of the substrate 302 on which the well region 313 is provided and the transistor 307 is arranged are arranged so as to face each other. On the other hand, in the arrangement shown in FIG. 5, the substrate 301 is arranged between the light emitting element 200 and the substrate 302. Further, the surface 361 of the substrate 301 on the opposite side of the surface 351 on which the well region 309 is provided and the transistor 304 is arranged and the surface 352 of the substrate 302 on which the well region 313 is provided and the transistor 307 is arranged are arranged so as to face each other. Points different from the arrangements shown in FIGS. 3 and 4 will be described below, and a description of the arrangement that may be similar to the arrangements shown in FIGS. 3 and 4 will be omitted, as appropriate.

An insulating layer 501 is arranged on the surface 361 of the substrate 301. An insulating layer 502 is arranged on the surface 352 of the substrate 302. The substrate 301 and the substrate 302 are bonded to each other via the insulating layer 501 and the insulating layer 502. A contact plug 504 that electrically connects the wiring layer 318 arranged above the surface 351 of the substrate 301 and the transistor 307 arranged on the surface 352 of the substrate 302 is provided in an element isolation region 503 provided so as to extend through the substrate 301. For the insulating layers 501 and 502, for example, silicon oxide, silicon nitride, a silicon carbide film, or the like can be used. For the contact plug 504, for example, copper, tungsten, aluminum, or an alloy thereof can be used.

The element isolation region 503 can be formed to have a depth to which it extends through the substrate 301 so the contact plug 504 is not electrically connected to the semiconductor region of the substrate 301. However, the present invention is not limited to this. For example, the contact plug 504 and the substrate 301 may be in contact with each other in a region of the substrate 301 other than the well region 309.

The insulating layer 323 is arranged between the surface 351 of the substrate 301 and the light emitting element 200. The wiring layer 318 arranged in the insulating layer 323 and the electrode 322 of the light emitting element 200 are electrically connected via a conductive plug 505. For example, silicon oxide, silicon nitride, or a silicon carbide film can be used for the insulating layer 323. For example, copper, tungsten, aluminum, or an alloy thereof can be used for the conductive plug 505. As shown in FIG. 5, the wiring pattern arranged in the wiring layer 318 can be connected to the transistors 304 and 305 arranged on the surface 351 of the substrate 301, and the transistor 307 arranged on the surface 352 of the substrate 302. Further, the wiring pattern arranged in the wiring layer 318 can be connected to various kinds of elements such as the transistors arranged on the surfaces 351 and 352 of the substrates 301 and 302, respectively.

In the arrangement shown in FIG. 5, the transistor 305 is arranged in the peripheral circuit portion 103 of the substrate 301, but no transistor 308 is arranged in the peripheral circuit portion 103 of the substrate 302. However, the transistor 308 as in the above description may be arranged in the peripheral circuit portion 103 of the substrate 302. In the peripheral circuit portion 103, an element such as the transistor 305 arranged in the substrate 301 and an element such as the transistor 308 arranged in the substrate 302 may be connected by, for example, the contact plug 504. Alternatively, for example, in the peripheral circuit portion 103, an element such as the transistor 305 arranged in the substrate 301 and an element such as a transistor arranged in the substrate 302 may be connected via a silicon penetrating electrode (TSV) provided in the substrate 301. The TSV can be formed by forming an insulating layer on the surface of a through hole extending through the substrate 301 made of silicon or the like and embedding a metal plug made of copper or the like in the through hole by using a plating method or the like. In this case, a barrier layer using titanium nitride or the like may be further arranged between the insulating layer and the metal plug. Although no wiring layer is illustrated between the substrate 301 and the substrate 302, a wiring layer may be arranged therebetween. At this time, for example, the wiring bonding portion 319 including a Cu—Cu bonding as shown in FIGS. 3 and 4 may be arranged in the bonding portion between the insulation layer 501 and the insulating layer 502. The wiring pattern arranged in the wiring layer between the insulating layer 501 and the insulating layer 502 can be connected to, for example, various kinds of elements such as a transistor arranged on the surface 352 of the substrate 302.

In the arrangement shown in FIG. 5, the wiring layer 318 including the wiring pattern arranged along the surface 351 of the substrate 301 is arranged between the surface 351 of the substrate 301 and the light emitting element 200. Therefore, the arrangement shown in FIG. 5 can increase the physical distance from the light emitting element 200 to the substrates 301 and 302 where the transistors are arranged, as compared to the structures shown in FIGS. 3 and 4. It can also be said that the arrangement shown in FIG. 5 can increase the physical distance from the light emitting element 200 to the transistors 304, 305, 307, and 308 arranged in the substrates 301 and 302. Hence, it is possible to suppress an off leakage current of each of the transistors 304 and 307 arranged in the pixel 104 of the light emitting device 101 while suppressing a deterioration of the characteristics of the organic layer 325 (light emitting layer) due to an influence of heat generated during driving of the transistors 304, 305, 307, and 308.

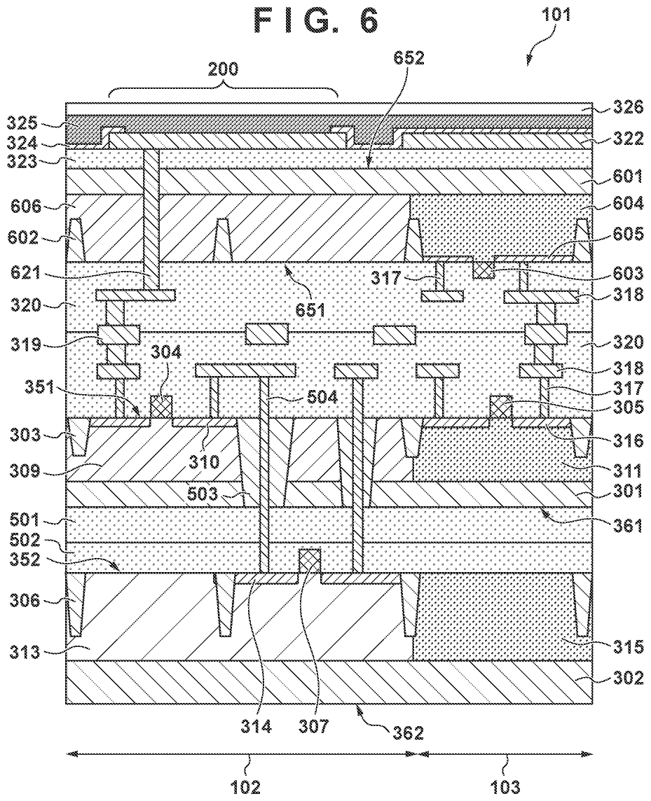

FIG. 6 is a sectional view showing an example of the arrangement of the light emitting device 101, and shows a modification of the sectional view shown in FIG. 5. In addition to the arrangement shown in FIG. 5, the arrangement shown in FIG. 6 further includes a substrate 601 stacked on the substrate 301 and the substrate 302. Points different from the arrangement shown in FIG. 5 will be described below, and a description of the arrangement that may be similar to the arrangement shown FIG. 5 will be omitted, as appropriate.

The substrate 601 stacked on the substrates 301 and 302 may be a single-crystal silicon substrate or an SOI substrate, like the substrates 301 and 302. A description will be given assuming that the conductivity type of the substrate 601 is the p type in the arrangement shown in FIG. 6.

Transistors 603 electrically isolated from each other by an element isolation region 602 formed by the STI method, the LOCOS method, or the like are arranged in the substrate 601. The transistor 603 can form the driving circuit for driving the pixel 104 (pixel array 102). It can also be said that at least a part of the driving circuit for driving the pixel 104 (pixel array) is arranged in the substrate 601. The transistors 305 and 308 forming the driving circuit are arranged in the peripheral circuit portion 103 in the substrates 301 and 302. On the other hand, the transistor 603 forming the driving circuit or the like may be arranged at, for example, a given position in the substrate 601 other than the portion where a conductive plug 621 electrically connects the electrode 322 of the light emitting element 200 and the transistor 304.

The transistor 603 may be an n-type transistor or a p-type transistor. For example, the transistor 603 is an n-type transistor, and a diffusion layer (to be sometimes referred to as a source/drain region 605 hereinafter) forming the source region or the drain region is arranged in a well region 604 as a p-type diffusion layer provided on a surface 651 of the p-type substrate 601. The source/drain region 605 is an n-type diffusion layer. As the transistors 603 arranged in the substrate 601, both an n-type transistor and a p-type transistor may be provided in the same substrate 601, or only the transistors of one conductivity type may be provided. In FIG. 6, no p-type transistor is illustrated in the substrate 601. However, if a transistor is arranged in a well region 606 provided on the surface 651 of the substrate 601, the conductivity type of the well region 606 is decided in accordance with the conductivity type of the transistor.

In the arrangement shown in FIG. 6, the substrate 601 is arranged between the light emitting element 200 and the substrates 301 and 302. Further, the surface 351 of the substrate 301 on which the well region 309 is provided and the transistor 304 is arranged and the surface 651 of the substrate 601 on which the well region 604 is provided and the transistor 603 is arranged are arranged so as to face each other.

Between the surface 351 of the substrate 301 and the surface 651 of the substrate 601, the contact plugs 317, the wiring layers 318, the wiring bonding portions 319, and the insulating layers 320 are arranged as a wiring structure. The transistor 603 is connected to the wiring layer 318 via the contact plug 317. Further, the wiring bonding portion 319 (including, for example, a Cu—Cu bonding) connects the wiring layers 318. With this, for example, the transistor 305 forming the driving circuit arranged in the peripheral circuit portion 103 of the substrate 301 is electrically connected to the transistor 603 forming the driving circuit arranged in the substrate 601.

As shown in FIG. 6, the transistor 304, which functions as the driving transistor 201 shown in FIG. 2, can be connected to the electrode 322 via the conductive plug 621 extending through the substrate 601. The conductive plug 621 is formed by embedding, via an insulating layer made of silicon oxide or the like, a metal such as copper, tungsten, or aluminum in a through hole provided in the substrate 601.

The transistor arranged in each of the pixel array 102, and the vertical scanning circuit 105 and the signal output circuit 106 in the peripheral circuit portion 103 in the light emitting device 101 is required to be a transistor having a higher breakdown voltage than the transistor arranged in the control circuit 107 in the peripheral circuit portion 103. On the other hand, the transistor arranged in the control circuit 107 in the peripheral circuit portion 103 is required to be a miniaturized and low-voltage driving transistor. In general, the dimension of a high breakdown voltage transistor is largely different from the dimension of a miniaturized and low-voltage driving transistor, and it is difficult to form them in the same substrate. Therefore, in the substrates 301 and 302, high breakdown voltage transistors are arranged as the transistors 304 and 307 forming the pixel 104 (pixel array 102) and the transistors 305 and 308 forming the vertical scanning circuit 105 and the signal output circuit 106 among the driving circuits. On the other hand, in the substrate 601, a miniaturized and low-voltage driving transistor is arranged as the transistor 603 forming the control circuit 107 among the driving circuits. It can also be said that the circuit arranged in the substrate 601 among the driving circuits includes the transistor 603, and the transistor 603 is a miniaturized transistor than the transistors 304, 305, 307, and 308 arranged in the substrates 301 and 302. With the arrangement as described above, it is possible to suppress an off leakage current of each of the transistors 304 and 307 arranged in the pixel 104 of the light emitting device 101 while increasing the operation speed of the light emitting device 101.

Also in the arrangement shown in FIG. 6, no transistor 308 is arranged in the peripheral circuit portion 103 of the substrate 302. However, the transistor 308 as in the above described may be arranged in the peripheral circuit portion 103 of the substrate 302. In the peripheral circuit portion 103, an element such as the transistor 305 arranged in the substrate 301 and an element such as the transistor 308 arranged in the substrate 302 may be connected by, for example, the contact plug 504. Alternatively, for example, in the peripheral circuit portion 103, an element such as the transistor 305 arranged in the substrate 301 and an element such as a transistor arranged in the substrate 302 may be connected via an TSV provided in the substrate 301.

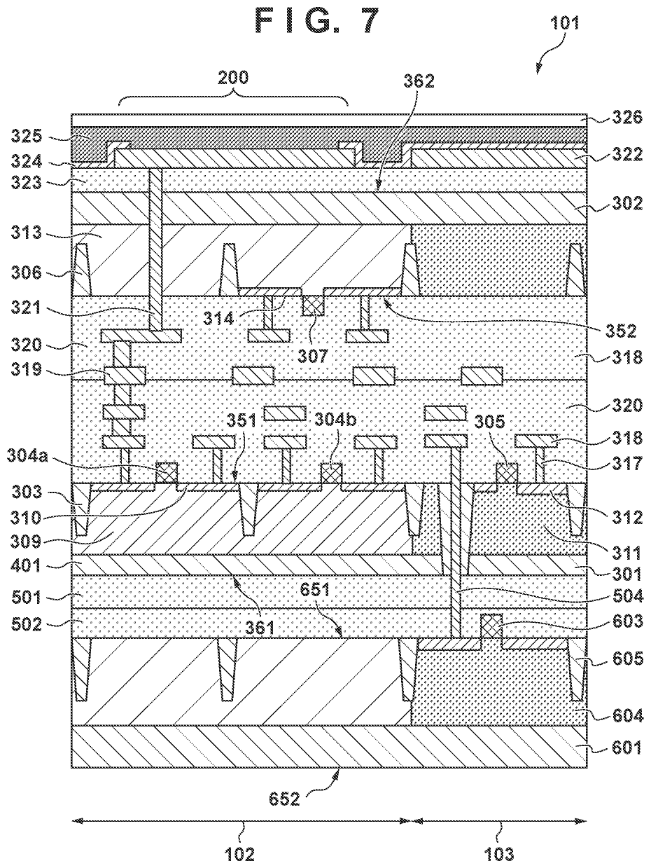

FIG. 7 is a sectional view showing an example of the arrangement of the light emitting device 101, and shows a modification of the sectional views shown in FIGS. 3 and 6. In addition to the arrangement shown in FIG. 3, the arrangement shown in FIG. 7 further includes the substrate 601 stacked on the substrate 301 and the substrate 302 as in the arrangement shown in FIG. 6. Points different from the arrangements shown in FIGS. 3 and 6 will be described below, and a description of the arrangement that may be similar to the arrangements shown in FIGS. 3 and 6 will be omitted, as appropriate.

In the arrangement shown in FIG. 7, the substrate 301 and the substrate 302 are arranged between the light emitting element 200 and the substrate 601. Further, the surface 361 of the substrate 301 on the opposite side of the surface 351 on which the well region 309 is provided and the transistor 304 is arranged and the surface 651 of the substrate 601 on which the well region 604 is provided and the transistor 603 is arranged are arranged so as to face each other.

The contact plug 504 that electrically connects the wiring layer 318 arranged above the surface 351 of the substrate 301 and the transistor 603 arranged on the surface 651 of the substrate 601 is provided in the element isolation region 503 provided so as to extend through the substrate 301. The transistor 603 may be electrically connected to, via the contact plug 504, the transistor 305 forming the driving circuit arranged in the peripheral circuit portion 103 of the substrate 301. Further, for example, in the peripheral circuit portion 103 or the like, an element such as the transistor 305 arranged in the substrate 301 and an element such as the transistor 603 arranged in the substrate 601 may be connected via an TSV provided in the substrate 301.

As has been described above, in the substrate 601, a miniaturized and low-voltage driving transistor can be arranged as the transistor 603 forming the control circuit 107 among the driving circuits. Accordingly, the control circuit 107 which operates at high speed can generate a larger amount of heat during operation than the pixel array 102, the vertical scanning circuit 105, and the signal output circuit 106. With the arrangement shown in FIG. 7, it is possible to increase the physical distance from the light emitting element 200 to the substrate 601 where the transistor 603 functioning as the control circuit 107 requiring a high-speed operation is arranged. Hence, it is possible to suppress an off leakage current of each of the transistors 304 and 307 arranged in the pixel 104 of the light emitting device 101 while suppressing a deterioration of the characteristics of the organic layer 325 (light emitting layer) due to an influence of heat generated during operating the light emitting device 101.

The arrangement of the light emitting device 101 that can implement high resolution and high image quality has been described above. The respective arrangements of the light emitting device 101 described above can be used in combination, as appropriate. A part of the arrangement of the light emitting device 101 described above may be omitted.

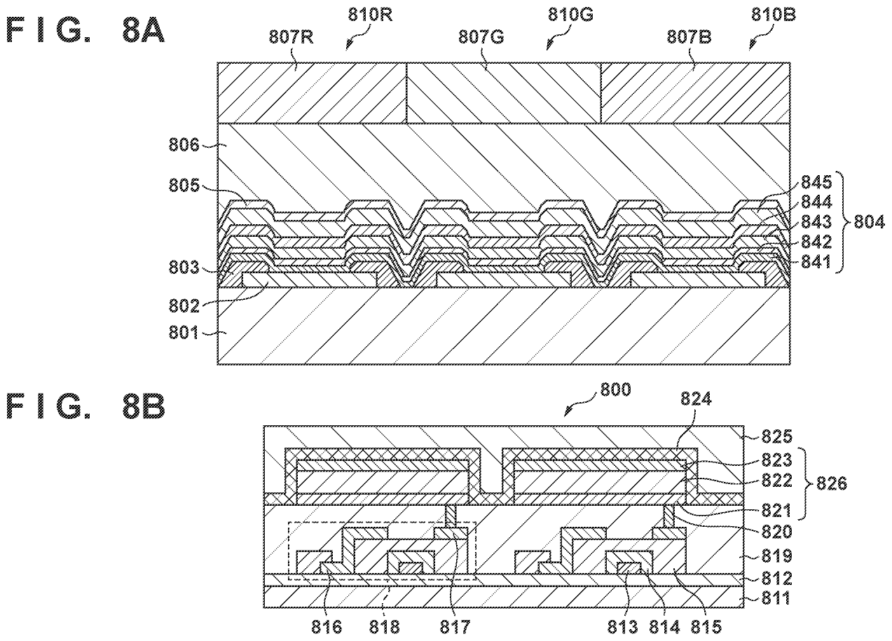

Here, application examples in which the light emitting device 101 according to this embodiment is applied to an image forming device, a display device, a photoelectric conversion device, an electronic apparatus, an illumination device, a moving body, and a wearable device will be described with reference to FIGS. 8A to 16B. The description will be given assuming that, for example, an organic light emitting element such as an organic EL element is arranged as the light emitting element 200 in the pixel 104 arranged in the pixel array 102 of the light emitting device 101 as has been described above. Details of each component arranged in the pixel array 102 of the light emitting device 101 described above will be described first, and the application examples will be described after that.

### Arrangement of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case in which a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer may be 10 nm (inclusive) to 150 nm (inclusive). A similar effect can be obtained in an arrangement including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this arrangement, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

More details will be described next with reference to the accompanying drawings. FIG. 8A shows an example of a pixel as a constituent element of the above-described pixel array 102. The pixel includes sub-pixels 810 (pixels 104). The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer may be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

A display device 800 (corresponding to the above-described light emitting device 101) shown in FIG. 8B is provided with an organic light emitting element 826 and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 8B. That is, one of the anode and cathode and one of the source electrode and drain electrode of the TFT are electrically connected. The TFT indicates a thin-film transistor.

In the display device 800 shown in FIG. 8B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display device 800 shown in FIG. 8B but may be used as another switching element.

The transistor used in the display device 800 shown in FIG. 8B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 800 shown in FIG. 8B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

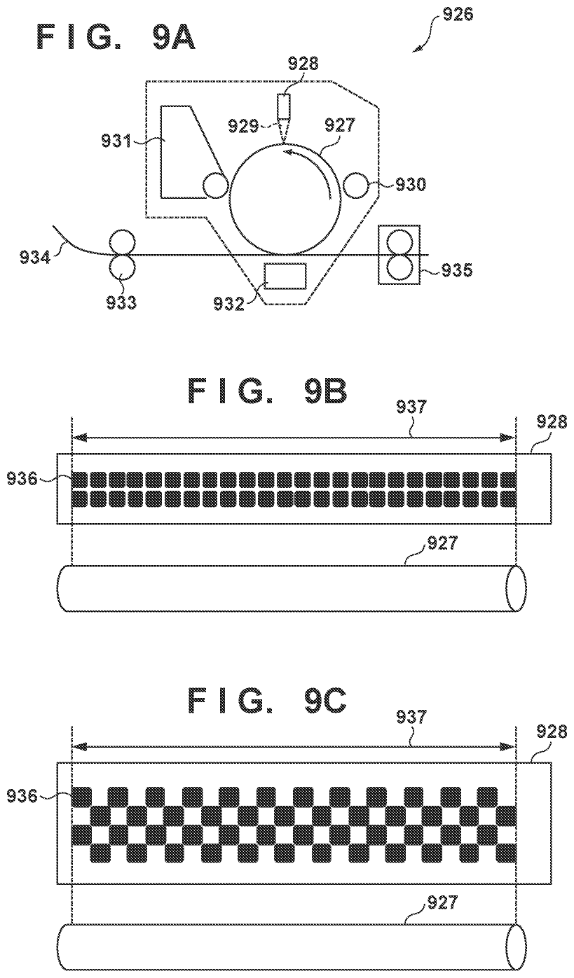

FIGS. 9A to 9C are schematic views showing an example of an image forming device using the light emitting device 101 according to this embodiment. An image forming device 926 shown in FIG. 9A includes a photosensitive member 927, an exposure light source 928, a developing unit 931, a charging unit 930, a transfer device 932, a conveyance unit 933 (a conveyance roller in the arrangement shown in FIG. 9A), and a fixing device 935.

Light 929 is emitted from the exposure light source 928, and an electrostatic latent image is formed on the surface of the photosensitive member 927. The light emitting device 101 can be applied to the exposure light source 928. The developing unit 931 can function as a developing device that contains a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper or a film. The fixing device 935 fixes the image formed on the print medium.

Each of FIGS. 9B and 9C is a schematic view showing a plurality of light emitting units 936 arranged along the longitudinal direction on a long substrate in the exposure light source 928. The light emitting device 101 can be applied to the light emitting units 936. That is, the plurality of pixels 104 arranged in the pixel array 102 are arranged along the longitudinal direction of the substrate. A direction 937 is a direction parallel to the axis of the photosensitive member 927. This column direction matches the direction of the axis upon rotating the photosensitive member 927. This direction 937 can be referred to as the long-axis direction of the photosensitive member 927.

FIG. 9B shows a form in which the light emitting units 936 are arranged along the long-axis direction of the photosensitive member 927. FIG. 9C shows a form, which is a modification of the arrangement of the light emitting units 936 shown in FIG. 9B, in which the light emitting units 936 are arranged in the column direction alternately between the first column and the second column. The light emitting units 936 are arranged at different positions in the row direction between the first column and the second column. In the first column, multiple light emitting units 936 are arranged spaced apart from each other. In the second column, the light emitting unit 936 is arranged at the position corresponding to the space between the light emitting units 936 in the first column. Also in the row direction, multiple light emitting units 936 are arranged spaced apart from each other. The arrangement of the light emitting units 936 shown in FIG. 9C can be referred to as, for example, an arrangement in a grid pattern, an arrangement in a staggered pattern, or an arrangement in a checkered pattern.

FIG. 10 is a schematic view showing an example of the display device using the light emitting device 101 of this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 101 can be applied to the display panel 1005. The pixels 104 arranged in the pixel array 102 of the light emitting device 101 functioning as the display panel 1005 operate in a state in which they are connected to the active elements such as transistors arranged on the circuit board 1007.

The display device 1000 shown in FIG. 10 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

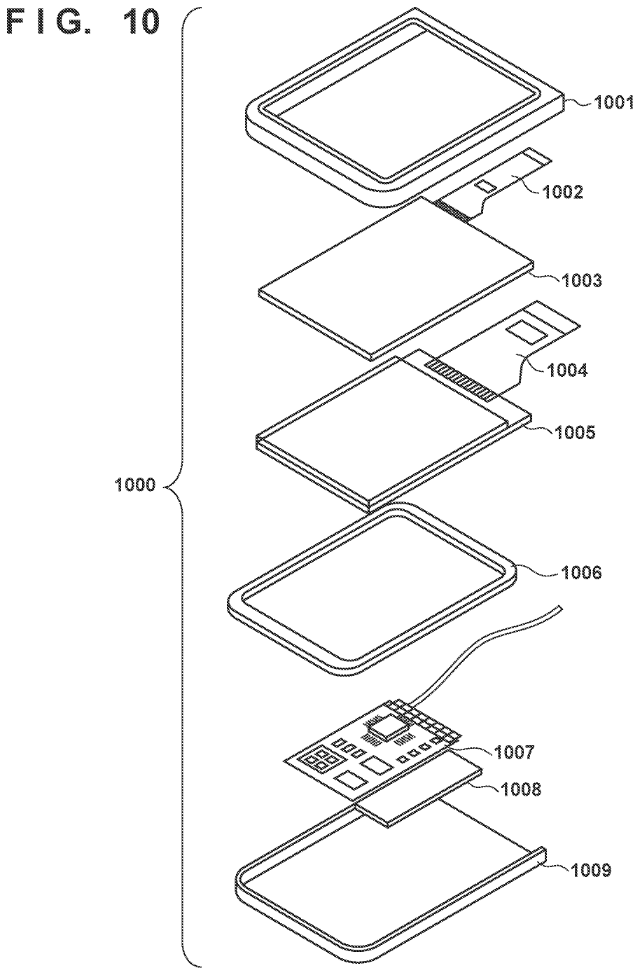

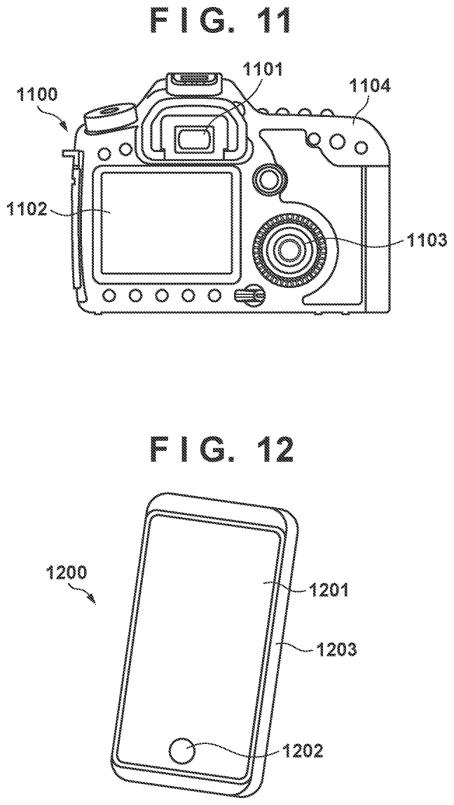

FIG. 11 is a schematic view showing an example of the photoelectric conversion device using the light emitting device 101 of this embodiment. A photoelectric conversion device 1100 can include a viewfinder 1101, a rear display 1102, an operation unit 1103, and a housing 1104. The photoelectric conversion device 1100 can also be called an image capturing device. The light emitting device 101 according to this embodiment can be applied to the viewfinder 1101 or the rear display 1102 as a display unit. In this case, the pixel array 102 of the light emitting device 101 can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, so the information should be displayed as soon as possible. Therefore, the light emitting device 101 in which the pixel 104 including the light emitting element using the organic light emitting material such as an organic EL element is arranged in the pixel array 102 may be used for the viewfinder 1101 or the rear display 1102. This is so because the organic light emitting material has a high response speed. The light emitting device 101 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 101 may be applied to a display unit of an electronic apparatus. At this time, the display unit can have both a display function and an operation function. Examples of the portable terminal are a portable phone such as a smartphone, a tablet, and a head mounted display.

FIG. 12 is a schematic view showing an example of an electronic apparatus using the light emitting device 101 of this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 101 according to this embodiment can be applied to the display unit 1201.

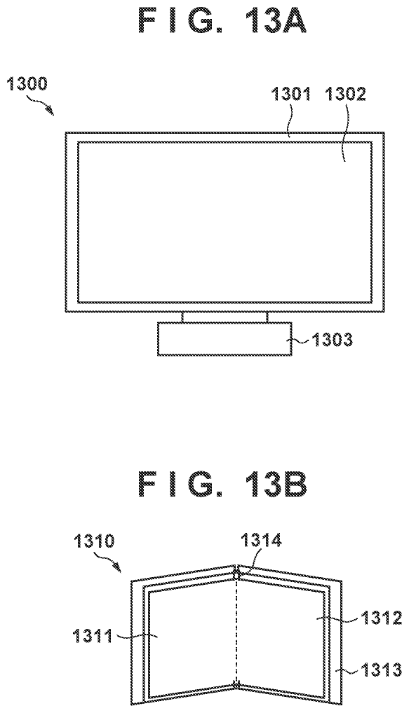

FIGS. 13A and 13B are schematic views showing examples of the display device using the light emitting device 101 of this embodiment. FIG. 13A shows a display device such as a television monitor or a PC monitor. A display device 1300 includes a frame 1301 and a display unit 1302. The light emitting device 101 according to this embodiment can be applied to the display unit 1302. The display device 1300 can include a base 1303 that supports the frame 1301 and the display unit 1302. The base 1303 is not limited to the form shown in FIG. 13A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 13B is a schematic view showing another example of the display device using the light emitting device 101 of this embodiment. A display device 1310 shown in FIG. 13B can be folded, and is a so-called foldable display device. The display device 1310 includes a first display unit 1311, a second display unit 1312, a housing 1313, and a bending point 1314. The light emitting device 101 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

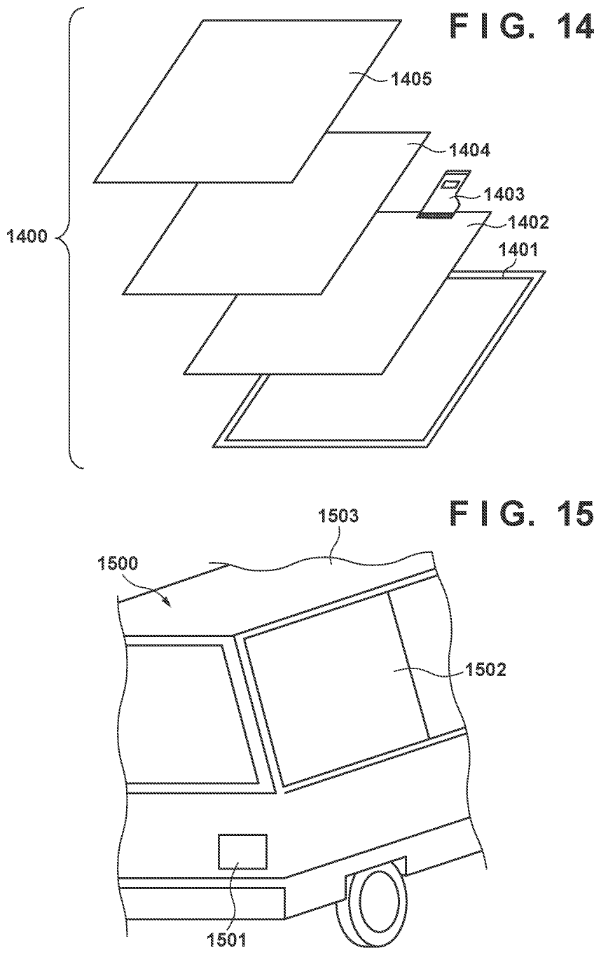

FIG. 14 is a schematic view showing an example of an illumination device using the light emitting device 101 according to this embodiment. An illumination device 1400 may include a housing 1401, a light source 1402, a circuit board 1403, an optical film 1404, and a light diffusion unit 1405. The light emitting device 101 according to this embodiment can be applied to the light source 1402. The optical film 1404 may be a filter that improves the color rendering property of the light source. The light diffusion unit 1405 can effectively diffuse light from the light source to illuminate a wide range for lighting up or the like. A cover may be provided in the outermost portion, as needed. The illumination device 1400 may include both the optical film 1404 and the light diffusion unit 1405, or may include only one of them.

The illumination device 1400 is, for example, a device that illuminates a room. The illumination device 1400 may emit light of white, day white, or any other color from blue to red. The illumination device 1400 may include a light control circuit for controlling the light color. The illumination device 1400 may 1400 may include a power supply circuit connected to the light emitting device 101 which functions as the light source 1402. The power supply circuit is a circuit that converts an AC voltage into a DC voltage. Note that white light has a color temperature of 4200K, and day-white light has a color temperature of 5000K. The illumination device 1400 may also include a color filter. Further, the illumination device 1400 may include a heat dissipation portion. The heat dissipation portion releases the heat in the device to the outside of the device, and examples thereof include a metal having high specific heat, liquid silicon, and the like.

FIG. 15 is a schematic view showing an automobile including a tail lamp which is an example of the lighting unit for an automobile using the light emitting device 101 according to this embodiment. An automobile 1500 includes a tail lamp 1501, and may turn on the tail lamp 1501 when a brake operation or the like is performed. The light emitting device 101 according to this embodiment may be used in a head lamp as the lighting unit for an automobile. The automobile is an example of a moving body, and the moving body may be a ship, a drone, an aircraft, a railroad car, an industrial robot, or the like. The moving body may include a body and a lighting unit provided in the body. The lighting unit may inform the current position of the body.

The light emitting device 101 according to this embodiment can be applied to the tail lamp 1501. The tail lamp 1501 may include a protective member that protects the light emitting device 101 which functions as the tail lamp 1501. The protective member has a certain degree of strength, and can be made from any material as long as it is transparent. The protective member may be made from polycarbonate or the like. Further, the protective member may be made from polycarbonate mixed with furandicarboxylic acid derivative, acrylonitrile derivative, or the like.

The automobile 1500 may include a body 1503 and windows 1502 attached thereto. The window may be a window for checking the front or rear of the automobile, or may a transparent display such as a head-up display. The light emitting device 101 according to this embodiment may be used in the transparent display. In this case, the components such as the electrodes included in the light emitting device 101 are formed by transparent members.

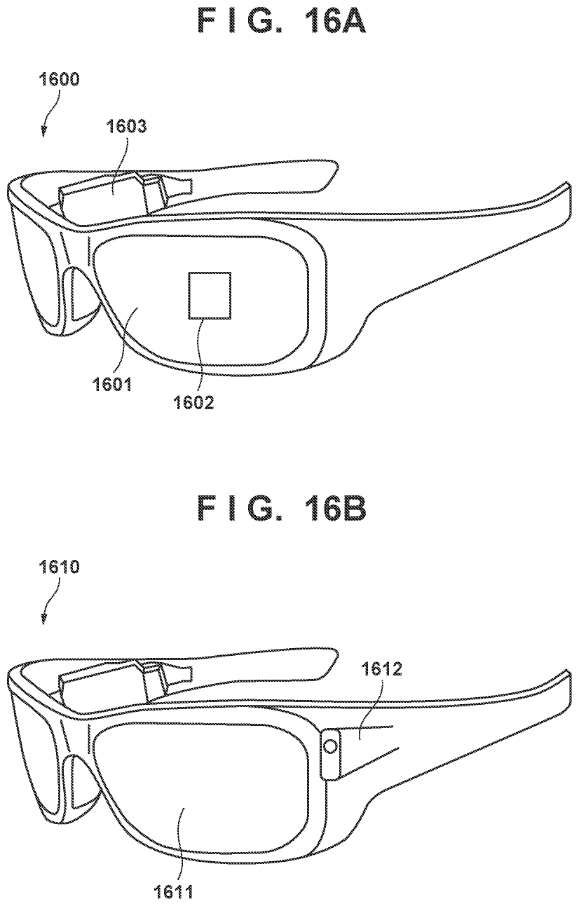

Further application examples of the light emitting device 101 according to this embodiment will be described with reference to FIGS. 16A and 16B. The light emitting device 101 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 16A. An image capturing device 1602 such as a CMOS sensor or an SPAD is provided on the surface side of a lens 1601 of the glasses 1600. In addition, the light emitting device 101 according to this embodiment is provided on the back surface side of the lens 1601.

The glasses 1600 further include a control device 1603. The control device 1603 functions as a power supply that supplies electric power to the image capturing device 1602 and the light emitting device 101 according to each embodiment. In addition, the control device 1603 controls the operations of the image capturing device 1602 and the light emitting device 101. An optical system configured to condense light to the image capturing device 1602 is formed on the lens 1601.

Glasses 1610 (smartglasses) according to one application example will be described with reference to FIG. 16B. The glasses 1610 include a control device 1612, and an image capturing device corresponding to the image capturing device 1602 and the light emitting device 101 are mounted on the control device 1612. The image capturing device in the control device 1612 and an optical system configured to project light emitted from the light emitting device 101 are formed in a lens 1611, and an image is projected to the lens 1611. The control device 1612 functions as a power supply that supplies electric power to the image capturing device and the light emitting device 101, and controls the operations of the image capturing device and the light emitting device 101. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 101 according to the embodiment of the present disclosure can include an image capturing device including a light receiving element, and control a displayed image based on the line-of-sight information of the user from the image capturing device.

More specifically, the light emitting device 101 decides a first visual field region at which the user is gazing and a second visual field region other than the first visual field region based on the line-of-sight information. The first visual field region and the second visual field region may be decided by the control device of the light emitting device 101, or those decided by an external control device may be received. In the display region of the light emitting device 101, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 101, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 101, the image capturing device, or an external device. If the external device holds the AI program, it is transmitted to the light emitting device 101 via communication.

When performing display control based on line-of-sight detection, smartglasses further including an image capturing device configured to capture the outside can be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-017008, filed Feb. 7, 2023, which is hereby incorporated by reference herein in its entirety.

What is claimed is:

1. A light emitting device that has a structure in which a first substrate and a second substrate are stacked on each other, and comprises a pixel including a light emitting element, a first transistor, and a second transistor,
wherein a source region and a drain region of the first transistor are arranged in a first well region provided on a first surface of the first substrate,
a source region and a drain region of the second transistor are arranged in a second well region provided on a second surface of the second substrate, and
a conductivity type of the first well region and a conductivity type of the second well region are different from each other.

2. The device according to claim 1, wherein
the light emitting element includes a light emitting layer and an electrode arranged between the light emitting layer and the first substrate, and
in an orthogonal projection with respect to the first surface, at least a part of the first transistor and at least a part of the second transistor are arranged so as to overlap the electrode.

3. The device according to claim 2, wherein
the second substrate is arranged between the light emitting element and the first substrate, and
the first transistor and the electrode are connected via a conductive plug extending through the second substrate.

4. The device according to claim 1, wherein
the first surface and the second surface are arranged so as to face each other.

5. The device according to claim 1, wherein
the first substrate is arranged between the light emitting element and the second substrate, and
a surface on an opposite side of the first surface of the first substrate and the second surface are arranged so as to face each other.

6. The device according to claim 5, wherein
a wiring layer including a wiring pattern is arranged between the first surface and the light emitting element.

7. The device according to claim 5, including a pixel array where the pixel is arranged, and a peripheral circuit portion arranged in a periphery of the pixel array,
wherein, in the peripheral circuit portion, an element arranged in the first substrate and an element arranged in the second substrate are connected via a TSV provided in the first substrate.

8. The device according to claim 1, further including a third substrate stacked on the first substrate and the second substrate,
wherein at least a part of a driving circuit configured to drive the pixel is arranged in the third substrate.

9. The device according to claim 8, wherein
the first substrate and the second substrate are arranged between the light emitting element and the third substrate.

10. The device according to claim 9, wherein
the first substrate is arranged between the second substrate and the third substrate, and
an element arranged in the first substrate and an element arranged in the third substrate are connected via a TSV provided in the first substrate.

11. The device according to claim 8, wherein
the third substrate is arranged between the light emitting element and the first substrate and the second substrate.

12. The device according to claim 8, wherein
a circuit, of the driving circuit, arranged in the third substrate includes a third transistor, and
the third transistor is a miniaturized transistor than the first transistor and the second transistor.

13. The device according to claim 1, wherein
the first substrate is a single-crystal silicon substrate or an SOI substrate, and
the second substrate is a single-crystal silicon substrate or an SOI substrate.

14. The device according to claim 1, wherein
a third well region having a conductivity type different from a conductivity type of the first well region is arranged in contact with the first well region and between a surface on an opposite side of the first surface of the first substrate and the first well region.

15. The device according to claim 1, wherein
the pixel further includes a MIS capacitor arranged in at least one of the first well region and the second well region.

16. The device according to claim 1, wherein
at least a part of a driving circuit configured to drive the pixel is arranged in at least one of the first surface and the second surface.

17. The device according to claim 1, wherein
the first transistor includes a driving transistor configured to supply a current corresponding to a luminance signal to the light emitting element.

18. The device according to claim 1, wherein
the second transistor includes a reset transistor configured to reset a potential difference between terminals of the light emitting element.

19. The device according to claim 1, wherein
the first transistor is a p-type transistor, and the second transistor is an n-type transistor.

20. An image forming device comprising a photosensitive member, an exposure light source configured to expose the photosensitive member, a developing device configured to apply a developing agent to the exposed photosensitive member, and a transfer device configured to transfer an image developed by the developing device to a print medium,
wherein the exposure light source includes the light emitting device according to claim 1.

21. A display device comprising the light emitting device according to claim 1, and an active element connected to the light emitting device.

22. A photoelectric conversion device comprising an optical unit including a plurality of lenses, an image sensor configured to receive light having passed through the optical unit, and a display unit configured to display an image,
wherein the display unit displays an image captured by the image sensor, and includes the light emitting device according to claim 1.

23. An electronic apparatus comprising a housing provided with a display unit, and a communication unit provided in the housing and configured to perform external communication,
wherein the display unit includes the light emitting device according to claim 1.

24. An illumination device comprising a light source, and at least one of a light diffusing unit and an optical film,
wherein the light source includes the light emitting device according to claim 1.

25. A moving body comprising a main body, and a lighting appliance provided in the main body,
wherein the lighting appliance includes the light emitting device according to claim 1.

26. A wearable device comprising a display device configured to display an image,
wherein the display device includes the light emitting device according to claim 1.
